(19) United States
(12) Patent Application Publication
(10) Pub. No.: US 2026/0190835 A1
(43) Pub. Date: Jul. 2, 2026

(54) Display Device

(71) Applicant: LG Display Co., Ltd., Seoul (KR)

(72) Inventors: Jungeun Lee, Seoul (KR); HwanKeon Lee, Gimpo-si (KR); Jeongbeom Lee, Seoul (KR); Junhyeok Lee, Seoul (KR)

(21) Appl. No.: 19/409,163

(22) Filed: Dec. 4, 2025

(30) Foreign Application Priority Data
Dec. 30, 2024 (KR) 10-2024-0200215

(51) Int. Cl. H10K 59/80; H10K 59/122

(52) U.S. Cl. CPC H10K 59/8792; H10K 59/122; H10K 59/879

(57) ABSTRACT

The present disclosure relates to a display device. More particularly, the display device includes a substrate in which a plurality of sub-pixels is defined, a thin film transistor disposed on the substrate, a planarization layer disposed on the thin film transistor, an organic light emitting element disposed on the planarization layer so as to correspond to each of the plurality of sub-pixels, an encapsulation layer disposed on the organic light emitting element, a touch sensor layer disposed on the encapsulation layer, a touch buffer layer disposed on the touch sensor layer, a plurality of color filters disposed to correspond to each of the plurality of sub-pixels on the touch buffer layer, a black matrix partitioning each of the plurality of color filters, and an over coating layer covering the black matrix, each of the plurality of color filters comprising a plurality of lenses.

### CROSS-REFERENCE TO RELATED APPLICATIONS

This application claims the benefit and priority to Republic of Korea Patent Application No. 10-2024-0200215 filed on Dec. 30, 2024, in the Korean Intellectual Property Office, the entire disclosure of which is incorporated herein by reference for all purposes, as if fully set forth herein.

### TECHNICAL FIELD

The present disclosure relates to a display device, and more particularly, for example, without limitation, to a display device in which a rainbow mura phenomenon is improved with a simplified structure and manufacturing process.

### DESCRIPTION OF THE RELATED ART

Unlike a liquid crystal display device (LCD) equipped with a backlight, light emitting display device such as an organic light emitting display device (OLED) does not require a separate light source. Therefore, it may be manufactured to be lightweight and thin, has process advantages, and has low power consumption due to low voltage driving.

Further, in order to provide more various functions to the user, such a display device may provide a function in which a touch sensor layer is disposed on the display panel and drives such a touch sensor layer to recognize the user's touch on the display panel and perform input processing based on the recognized touch.

Meanwhile, the organic light emitting display device includes an anode, a cathode, and a light emitting layer disposed therebetween. As a metal material having a high reflectance is usually used in the light emitting display device to form elements such as the cathode or the anode, external light is reflected by the metal material so that it is difficult for a user to easily identify displayed image.

The description provided in the background section should not be assumed to be prior art merely because it is mentioned in or associated with the background section. The background section may include information that describes one or more aspects of the subject technology.

### SUMMARY

The touch sensor layer may not include a separate adhesive layer, but may be disposed on the display panel in a touch on encapsulation (ToE) structure. In addition, a color filter and a black matrix may be disposed on the touch sensor layer to lower the above-described reflectance of external light. The black matrix may be disposed to correspond to the non-emission area, and the color filter may be disposed to correspond to the emission area of each of the plurality of sub-pixels. By arranging the color filter and the black matrix in this way, it is possible to lower the reflectance of external light without lowering the luminous efficiency.

In this structure, in order to secure a luminance viewing angle while lowering the reflectance of external light, a pull-back structure in which the width of the color filter is formed wider than the width of the corresponding emission area is also applied. However, it is newly recognized by inventors of the present disclosure that, when the pull-back structure is applied, the width of the black matrix is smaller than the width of the bank, so that the bank is not completely covered by the black matrix and is exposed. Accordingly, there is a problem that the rainbow mura phenomenon occurs due to the exposed bank and the display quality is deteriorated.

Accordingly, in order to reduce the rainbow mura phenomenon, an optical film having a pattern shape having a different refractive index was added on the color filter. Such an optical film has a micro-patterned shape, which subdivides the spatial luminance distribution of external light to scatter external light incident on the panel, thereby weakening the intensity of constructive/destructive interference, thereby improving the rainbow mura phenomenon.

However, when the optical film is provided, adhesive layers are disposed on the upper and lower portions, respectively, to complicate the structure and process of the display device, and it has limitation in reducing the thickness of the display device.

Accordingly, an aspect of the present disclosure is to provide a display device which reduces reflectance and improves a luminance viewing angle and a rainbow mura phenomenon.

Further, another aspect of the present disclosure is to provide a display device in which a structure is simplified and a thickness is reduced by omitting a complicated process step of bonding a separate optical film with an adhesive layer.

Aspects of the present disclosure are not limited to the above-mentioned aspects, and other aspects, which are not mentioned above, can be clearly understood by those skilled in the art from the following descriptions.

Additional features and aspects of the disclosure are set forth in part in the description that follows and in part will become apparent from the description or may be learned by practice of the inventive concepts provided herein. Other features and aspects of the inventive concepts may be realized and attained by the structures pointed out in the present disclosure, or derivable therefrom, and the claims hereof as well as the appended drawings.

To achieve these and other aspects of the inventive concepts, as embodied and broadly described herein, a display device includes a substrate on which a plurality of sub-pixels is defined, a thin film transistor disposed on the substrate, a planarization layer disposed on the thin film transistor, an organic light emitting element disposed on the planarization layer so as to correspond to each of the plurality of sub pixels, an encapsulation layer disposed on the organic light emitting element, a touch sensor layer disposed on the encapsulation layer and including a plurality of touch electrodes, a touch buffer layer disposed on the touch sensor layer, a plurality of color filters disposed to correspond to each of the plurality of sub pixels on the touch buffer layer, a black matrix partitioning each of the plurality of color filters, and an over coating layer covering the black matrix, wherein each of the plurality of color filters includes a plurality of lenses.

Other detailed matters of the embodiments are included in the detailed description and the drawings.

In the display device according to the present disclosure, it is possible to provide a display device in which the rainbow mura phenomenon is improved and reflectance is reduced even though an additional optical film is not provided over the color filter, due to the novel structure of the color filter itself.

Further, in the display device according to the present disclosure, the optical film and the adhesive layer for attaching the same are omitted and the structure and process steps of the display device can be simplified.

In addition, the display device according to the present disclosure may provide a slim display device by omitting an optical film.

The effects according to the present disclosure are not limited to the contents exemplified above, and more various effects are included in the present disclosure.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, that may be included to provide a further understanding of the disclosure and may be incorporated in and constitute a part of the disclosure, illustrate embodiments of the disclosure and together with the description serve to explain various principles of the disclosure.

The above and other aspects, features and other advantages of the present disclosure will be more clearly understood from the following detailed description taken in conjunction with the accompanying drawings, in which:

FIG. 1 is a plan view of a display device according to an example embodiment of the present disclosure.

FIG. 2 is an enlarged plan view of one pixel in the display device according to the example embodiment of the present disclosure.

FIG. 3 is an example cross-sectional view taken along the line I-I′ of FIG. 2.

FIG. 4 is an enlarged plan view of one pixel in a display device according to another example embodiment of the present disclosure.

FIG. 5 is an example cross-sectional view taken along the line II-II′ of FIG. 4.

FIG. 6 is a cross-sectional view of a display device according to still another example embodiment of the present disclosure.

FIG. 7 is a cross-sectional view of a display device according to still another example embodiment of the present disclosure.

FIG. 8 is a cross-sectional view of a display device according to still another example embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION OF THE EMBODIMENT

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure and a method of achieving the advantages and features will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure. Any implementation described herein as an “example” is not necessarily to be construed as preferred or advantageous over other implementations.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with a more limiting term such as “only.” An element described in the singular form is intended to include a plurality of elements, and vice versa, unless the context clearly indicates otherwise.

In construing an element, the element is construed as including an ordinary error range or tolerance range although there is no explicit description of such an error or tolerance range.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts may be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

In describing a temporal relationship, when the temporal order is described as, for example, “after,” “subsequent,” “next,” and “before,” a case that is not continuous may be included unless a more limiting term, such as “just,” “immediate(ly),” or “direct(ly)” is used.

When an element or layer is disposed “on” another element or layer, another layer or another element may be interposed directly on the other element or therebetween.

Although the terms “first”, “second”, “A”, “B”, “(a)”, “(b)” and the like are used for describing various components, the essence, sequence, order, or number of these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

In the description of embodiments, when a structure is described as being positioned “on or above” or “under or below” another structure, this description should be construed as including a case in which the structures contact each other as well as a case in which a third structure is disposed therebetween. A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning, for example, consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, a display device according to various exemplary embodiments of the present disclosure will be described in detail with reference to accompanying drawings. Further, all the components of each display device according to all embodiments of the present disclosure are operatively coupled and configured.

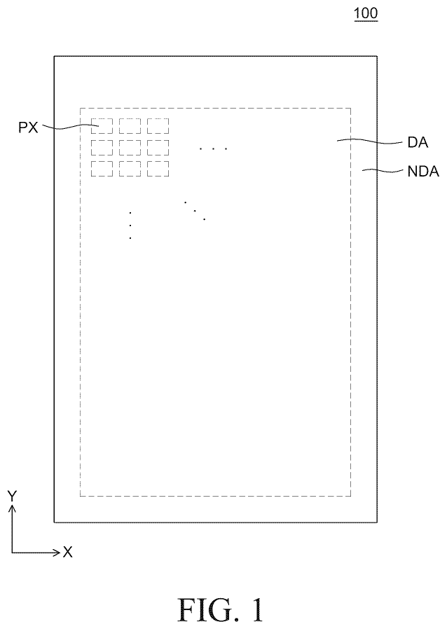

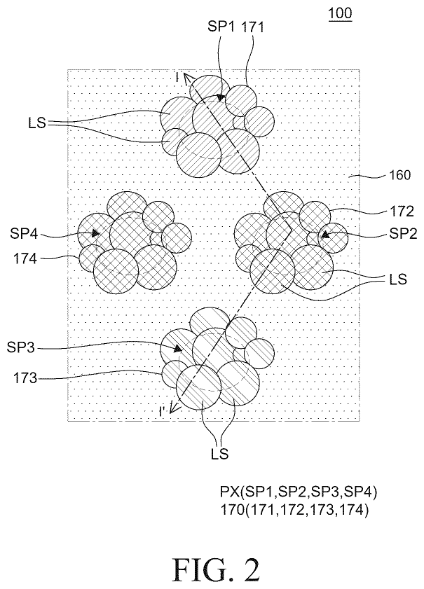

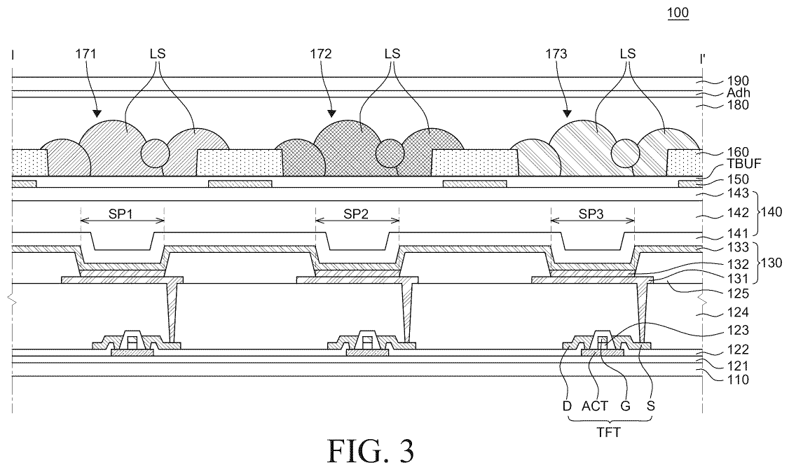

FIG. 1 is a plan view of a display device according to an embodiment of the present disclosure. FIG. 2 is an enlarged plan view of one pixel in the display device according to the embodiment of the present disclosure. FIG. 3 is a cross-sectional view taken along the line I-I′ of FIG. 2.

A display device 100 according to an exemplary embodiment of the present disclosure includes one or more of a substrate 110, a thin film transistor TFT, a planarization layer 124, an organic light emitting element 130, an encapsulation layer 140, a touch sensor layer 150, a black matrix 160, a color filter 170, and an over coating layer 180.

First, the display device 100 includes areas defined as a display area DA and a non-display area NDA adjacent to the display area DA. The display area DA is an area in which a plurality of pixels PX are disposed and an image is substantially displayed. In the display area DA, a pixel PX including an emission area for displaying an image and a driving circuit for driving the pixel PX may be disposed. The non-display area NDA may surround the display area DA. The non-display area NDA is an area where an image is not substantially displayed and various wiring lines, driving ICs, and printed circuit boards for driving the pixels PX disposed in the display area DA may be disposed in the non-display area NDA.

The plurality of pixels PX is arranged in a matrix shape, and each of the plurality of pixels PX includes a plurality of sub-pixels SP1, SP2, SP3, and SP4. The sub-pixels SP1, SP2, SP3, and SP4 are elements for displaying one color and include an emission area in which light is emitted and a non-emission area in which light is not emitted. In the present specification, only an emission area from which light is emitted is defined as a sub-pixel. For example, each of the plurality of sub-pixels may display any one of red, green, and blue colors, but is not limited thereto.

For example, one pixel PX may include a first sub-pixel SP1, a second sub-pixel SP2, a third sub-pixel SP3, and a fourth sub-pixel SP4. In the present disclosure, the four sub-pixels SP1 to SP4 are illustrated by way of example only, and each pixel may include two, three, five or more sub pixels which emit different color light. In the drawing, the shapes and arrangements of the first sub-pixel SP1, the second sub-pixel SP2, the third sub-pixel SP3, and the fourth sub-pixel SP4 are illustrated as an example, but are not limited thereto. The shape of each of the sub-pixels SP1, SP2, SP3, and SP4 may be a circle or an oval, or may be a polygonal shape such as a triangle, a square, a pentagon, a hexagon, or the like, but is not particularly limited.

The first sub-pixel SP1, the second sub-pixel SP2, the third sub-pixel SP3, and the fourth sub-pixel SP4 may display different colors, or if necessary, some sub-pixels may display the same color. For example, the first sub-pixel SP1 may be a red sub-pixel, the second sub-pixel SP2 and the fourth sub-pixel SP4 may be green sub-pixels, and the third sub-pixel SP3 may be a blue sub-pixel, but not limited thereto. As an example, a sub pixel which emits light of other colors such as cyan, magenta, or yellow, etc. may be alternatively or additionally included. Even though in the drawing, the sizes of the sub-pixels SP1, SP2, SP3, and SP4 are illustrated as the same, the areas may be formed to be different for each color displayed by the sub-pixels SP1, SP2, SP3, and SP4 in consideration of the luminance and the color temperature.

The substrate 110 is a substrate for supporting various elements constituting the display device. For example, the substrate 110 may be a glass substrate or a plastic substrate. For example, the plastic substrate may be selected from polyimide, polyethersulfone, polyethylene terephthalate, and polycarbonate, but is not limited thereto. In another example, the plastic substrate may include a plastic material having flexibility, such as any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC), polyvinyl alcohol (PVA), polyimide (PI), and polystyrene (PS), but the example embodiments of the present disclosure are not limited thereto. When a plastic substrate having flexibility is used, a support member such as a back plate may be disposed under the substrate 110. A plastic substrate having flexibility is relatively thin and less rigid than a glass substrate, so sagging may occur when various elements are disposed. The back plate supports the substrate 110 made of plastic so as not to sag and protects the display device 100 from moisture, heat, impact, and the like.

A substrate buffer layer 121 may be disposed on the substrate 110 to prevent or reduce permeation of oxygen or moisture. The substrate buffer layer 121 may be formed as a single layer, and may be formed in a multi-layered structure if necessary.

A thin film transistor TFT including a gate electrode G, an active layer ACT, a source electrode S, and a drain electrode D is disposed on the substrate buffer layer 121. The thin film transistor TFT is disposed in each of the first sub-pixel SP1, the second sub-pixel SP2, the third sub-pixel SP3, and the fourth sub-pixel SP4. In the drawing, for the convenience of description, only a driving thin film transistor among various thin film transistors that may be included in the display device 100 is illustrated.

The active layer ACT is disposed on the substrate buffer layer 121, and a gate insulating layer 123 for insulating the active layer ACT and the gate electrode G is disposed on the active layer ACT. Further, an interlayer insulating layer 122 for insulating the gate electrode G, the source electrode S, and the drain electrode D is disposed on the substrate buffer layer 121. The source electrode S and the drain electrode D respectively contacting the active layer ACT are formed on the interlayer insulating layer 122. It is to be noted that the source electrode S and the drain electrode D are not fixed, but may be interchanged with each other depending on the type of the thin film transistor TFT and the voltage difference applied between the source electrode S and the drain electrode D. Thus, the source electrode S and the drain electrode D may be referred to as first and second electrodes respectively.

A planarization layer 124 may be disposed on the thin film transistor TFT. The planarization layer 124 planarizes an upper portion of the thin film transistor TFT. The planarization layer 124 may include a contact hole for electrically connecting the thin film transistor TFT and the anode 131 of the organic light emitting element 130.

The organic light emitting element 130 is disposed on the planarization layer 124. The organic light emitting element 130 is disposed in each of the first sub-pixel SP1, the second sub-pixel SP2, the third sub-pixel SP3, and the fourth sub-pixel SP4. The organic light emitting elements 130 disposed in each of the sub-pixels SP1, SP2, SP3, and SP4 include an anode 131, an emission layer 132, and a cathode 133.

The anode 131 is disposed on the planarization layer 124. The anode 131 may be patterned to correspond to each of the plurality of sub-pixels SP1, SP2, SP3, and SP4. For example, the anode 131 may be formed to be separated for each of the first sub-pixel SP1, the second sub-pixel SP2, the third sub-pixel SP3, and the fourth sub-pixel SP4. The anode 131 is formed of a conductive material having a high work function as a component for supplying holes to the emission layer 132. The anode 131 may be a transparent conductive layer formed of transparent conductive oxide (TCO). For example, the anode 131 may be formed of one or more selected from transparent conductive oxides such as indium-tin-oxide (ITO), indium-zinc-oxide (IZO), indium-tin-zinc oxide (ITZO), tin oxide (SnO₂), zinc oxide (ZnO), indium-copper-oxide (ICO), and aluminum-doped zinc oxide (Al-doped ZnO, AZO), but is not limited thereto.

When the display device 100 is driven as a top emission type, the anode 131 may further include a reflective layer to reflect light emitted from the organic emission layer 132 toward the cathode 133.

The bank 125 is disposed on the anode 131 and the planarization layer 124. The bank 125 is disposed to cover an edge of the anode 131 of the organic light emitting element 130. For example, the bank 125 may cover an edge of the anode 131 to define a light emitting area. The bank 125 may divide the plurality of sub-pixels SP1, SP2, SP3, and SP4. The bank 125 may be formed of an insulating material to insulate anodes 131 of adjacent sub-pixels SP1, SP2, and SP3 from each other. Further, the bank 125 may be configured by a black bank having a high light absorption rate to prevent or reduce color mixture between adjacent sub-pixels SP1, SP2, and SP3. The black bank may absorb external light introduced into the display device 100 by passing through the color filter 170 and the black matrix 160 to be described later. Accordingly, it is possible to improve the reflective visibility by lowering the reflectance of external light. For example, the bank 125 may be formed of polyimide resin, acrylic resin, or benzocyclobutene resin, and may further include a black colorant or a dye of different colors in the organic material.

The cathode 133 is disposed on the anode 131. The cathode 133 may be formed of a metal material having a low work function to smoothly supply electrons to the organic emission layer 132. For example, the cathode 133 may be formed of a metal material selected from calcium (Ca), barium (Ba), aluminum (Al), silver (Ag), and an alloy including one or more of them, but is not limited thereto. The cathode 133 may be formed on the anode 131 as one layer. For example, the cathode 133 may be formed as a common layer without being separated, corresponding to each of the first sub-pixel SP1, the second sub-pixel SP2, the third sub-pixel SP3, and the fourth sub-pixel SP4. When the display device 100 is driven as a top emission type, the cathode 133 may be formed to have a very thin thickness to be substantially transparent.

The organic emission layer 132 is disposed between the anode 131 and the cathode 133. The organic emission layer 132 is a layer in which electrons and holes are combined to emit light. For example, the organic emission layer 132 may be formed in a separate structure corresponding to each of the plurality of sub-pixels SP1, SP2, SP3, and SP4. In this case, the organic emission layer 132 is configured to emit light having the same color as that of a corresponding sub-pixel.

For example, the organic emission layer 132 corresponding to the first sub-pixel SP1 may be a red organic emission layer, the organic emission layer 132 corresponding to the second sub-pixel SP2 and the fourth sub-pixel SP4 may be a green organic emission layer, and the organic emission layer 132 corresponding to the third sub-pixel SP3 may be a blue organic emission layer. However, the present disclosure is not limited thereto. As another example, the organic emission layer 132 may be formed as a common layer without being separated structure corresponding to each of the plurality of sub-pixels SP1, SP2, SP3, and SP4. In this case, the organic emission layer 132 is configured to emit white light, and light having a color corresponding to each sub-pixel SP1, SP2, SP3, or SP4 may be emitted through the color filter 170.

The organic light emitting element 130 may further include a hole injection layer, a hole transport layer, an electron transport layer, an electron injection layer, and the like to improve luminous efficiency. For example, a hole injection layer and a hole transport layer may be disposed between the anode 131 and the organic emission layer 132, and an electron transport layer and an electron injection layer may be disposed between the organic emission layer 132 and the cathode 133. In addition, a hole blocking layer or an electron blocking layer may be disposed to further improve the recombination efficiency of holes and electrons in the organic emission layer 132.

The encapsulation layer 140 is disposed on the organic light emitting element 130. The encapsulation layer 140 may cover the organic light emitting element 130. The encapsulation layer 140 may protect the organic light emitting element 130 from external moisture, oxygen, impact, and the like. The encapsulation layer 140 may have a multi-layered structure in which an inorganic layer formed of an inorganic insulating material and an organic layer formed of an organic material are stacked. For example, the encapsulation layer 140 may be configured by at least one organic layer and at least two inorganic layers, and may have a multilayer structure in which inorganic layers and organic layers are alternately stacked, but is not limited thereto.

For example, the encapsulation layer 140 may have a triple-layered structure including a first inorganic layer 141, an organic layer 142, and a second inorganic layer 143. In this case, the first inorganic layer 141 and the second inorganic layer 143 may be independently formed of one or more selected from silicon nitride (SiNx), silicon oxide (SiOx), aluminum oxide (AlOx), and silicon oxynitride (SiON), but are not limited thereto. In addition, the organic layer 142 may be formed of one or more selected from epoxy resin, polyimide, polyethylene, and silicon oxycarbide (SiOC), but is not limited thereto.

For example, the encapsulation layer 140 may have a triple-layered structure including a first inorganic layer 141, an organic layer 142, and a second inorganic layer 143. In this case, the first inorganic layer 141 and the second inorganic layer 143 may be independently formed of one or more selected from silicon nitride (SiNx), silicon oxide (SiOx), aluminum oxide (AlOx), and silicon oxynitride (SiON), but are not limited thereto. Further, the organic layer 142 may be formed of one or more selected from epoxy resin, acrylic resin, silicone resin, polyimide, polyethylene, and silicon oxycarbide (SiOC), but is not limited thereto.

The touch sensor layer 150 is disposed on the encapsulation layer 140 to impart a touch sensing function to the display device 100. The touch sensor layer 150 is formed in a touch on encapsulation (ToE) structure in which the touch sensor layer 150 is formed on the encapsulation layer 140 without a separate substrate or an adhesive member in the display device 100 according to an embodiment of the present disclosure. In such a structure, when the distance between the organic light emitting element 130 and the touch sensor layer 150 is too short, parasitic capacitance is generated, thereby reducing touch sensitivity. Accordingly, the thickness of the encapsulation layer 140 may be appropriately adjusted to minimize or reduce the parasitic capacitance.

Although not illustrated in the drawings, an encap protection layer may be disposed on the encapsulation layer 140. In the process of forming the touch sensor layer 150 on the encapsulation layer 140, the encap protection layer may be disposed to protect the encapsulation layer 140, the organic light emitting element 130, and the like disposed therebelow. In addition, the encap protective layer improves adhesion between the touch electrode to be described later and the encapsulation layer 140. Further, the encap protection layer may protect a signal line or a pad unit disposed in the non-display area NDA from being damaged in the non-display area NDA. The encap protection layer may be formed of an inorganic insulating material, for example, one or more selected from silicon nitride (SiNx), silicon oxide (SiOx), aluminum oxide (AlOx), and silicon oxy nitride (SiON), but is not limited thereto.

The touch sensor layer 150 includes a plurality of touch electrodes. The plurality of touch electrodes are layers including electrodes for sensing a touch input, and may include a plurality of sensing electrodes and a plurality of driving electrodes, and may detect touch coordinates by sensing a change in capacitance between the plurality of sensing electrodes and the plurality of driving electrodes. For example, the sensing electrode and the driving electrode may be disposed on the same plane, and at least some of the plurality of touch electrodes may be electrically connected through a bridge electrode disposed on the other plane with an insulating layer therebetween. However, the present disclosure is not limited thereto, and the configuration of the touch sensor layer 150 may be variously changed as necessary. For example, when the touch sensor layer 150 is implemented in a self-capacitance scheme, the touch sensor layer 150 may include a plurality of touch sensing electrodes disposed on a same plane and separated from each other.

Each of the plurality of touch electrodes may be disposed to correspond to a boundary or the non-emission area of the sub-pixels SP1, SP2, SP3, and SP4. For example, the touch electrode may be disposed on the encap protection layer so as to correspond between adjacent color filters 170. In this case, the efficiency of light emitted from the organic light emitting element 130 may be maintained high without deteriorating, and the touch electrode is not visually recognized from the outside, so the display quality is excellent. The touch electrode may be formed of a transparent metal material such as indium-tin-oxide (ITO) or indium-zinc-oxide (IZO) capable of transmitting light. However, the present disclosure is not limited thereto, and the configuration, material, and the like of the touch sensor layer 150 may be variously changed according to design.

The touch buffer layer TBUF is disposed on the touch electrode. The touch buffer layer TBUF is disposed to cover the touch electrode.

The touch buffer layer TBUF protects the touch electrode from being damaged during a process of forming the black matrix 160 and the color filter 170 on the touch electrode. In addition, the touch buffer layer TBUF may prevent or reduce the penetration of moisture or oxygen from the outside and thus protect the touch electrode from being deteriorated.

The touch buffer layer TBUF may have hydrophobicity. In this case, the color filter 170 including the plurality of lenses LS may be easily formed on the touch buffer layer TBUF. For example, the touch buffer layer TBUF may be formed of one or more inorganic insulating materials selected from silicon nitride (SiNx), silicon oxide (SiOx), aluminum oxide (AlOx), and silicon oxynitride (SiON), but is not limited thereto.

A plurality of color filters 170 and a black matrix 160 are disposed on the touch buffer layer TBUF. The plurality of color filters 170 and the black matrix 160 may serve as an anti-reflection layer which absorbs external light while maintaining high luminance of light emitted from the organic light emitting element 130 and minimizes or reduces degradation of visibility and contrast ratio of the display device 100 due to the external light.

The black matrix 160 is disposed on the touch buffer layer TBUF so as to overlap the bank 125. Accordingly, the black matrix 160 is disposed to correspond to the touch electrode.

The black matrix 160 is formed of a material having a high light absorption rate. Accordingly, the black matrix 160 absorbs external light and at least partially prevents visibility from being reduced by reflected light. The black matrix 160 is formed to have a width greater than a width of each of the plurality of touch electrodes. Accordingly, the touch electrode is covered by the black matrix 160 and is not visually recognized from the outside. Further, the touch electrode has a characteristic in which reflectance is higher than that of the black matrix 160 due to the characteristics of the material itself, and as the black matrix 160 is disposed on the touch electrode, the problem in that external light is reflected by the touch electrode to degrade the visibility may be improved.

The black matrix 160 may include a base resin and a black material. For example, the base resin may be one or more selected from cardo-based resin, epoxy-based resin, acrylate-based resin, siloxane-based resin, and polyimide, but is not limited thereto. For example, the black material may be a black pigment selected from a carbon-based pigment, a metal oxide-based pigment, and an organic pigment. For example, the carbon-based pigment may be carbon black. For example, the metal oxide-based pigment may be titanium black (TiNxOy), a Cu—Mn—Fe-based black pigment, or the like, but is not limited thereto. For example, the organic pigment may be selected from lactam black, perylene black, and aniline black, but is not limited thereto. Further, as the black material, an RGB black pigment including a red pigment, a blue pigment, and a green pigment may be used, but the present disclosure is not limited thereto.

The black matrix 160 is disposed on the touch buffer layer TBUF to be positioned between adjacent sub-pixels SP1, SP2, SP3, and SP4. For example, the black matrix 160 is disposed along the boundary of the adjacent sub-pixels SP1, SP2, SP3, and SP4 and includes an opening at a position corresponding to the sub-pixels SP1, SP2, SP3, and SP4. Accordingly, light emitted from the organic light emitting element 130 may be emitted to the outside through the opening of the black matrix 160.

A distance between the black matrices 160 adjacent to each other may be formed to be greater than a distance between adjacent banks 125. In this case, light emitted from the organic light emitting element 130 is emitted at a wide angle, thereby securing an advantage of excellent luminance viewing angle.

The plurality of color filters 170 is disposed on the touch buffer layer TBUF so as to correspond to each of the plurality of sub-pixels SP1, SP2, SP3, and SP4. The color filter 170 includes a first color filter 171 corresponding to the first sub-pixel SP1, a second color filter 172 corresponding to the second sub-pixel SP2, a third color filter 173 corresponding to the third sub-pixel SP3, and a fourth color filter 174 corresponding to the fourth sub-pixel SP4. The color filter 170 may be configured to transmit light of the same color as the corresponding sub-pixels SP1, SP2, SP3, and SP4.

Each of the plurality of color filters 170 includes a plurality of lenses LS. For example, each of the first color filter 171, the second color filter 172, the third color filter 173, and the fourth color filter 174 includes a plurality of lenses LS. As described above, as the color filter 170 includes the plurality of lenses LS, the propagation speed of external light may be changed due to the difference in refractive index between the color filter 170 and the over coating layer 180 to be described later. Further, because of the plurality of lenses LS, the surface of the color filter has a non-flat surface, the path of the light incident from the outside is variously changed, such that the spatial luminance distribution of the external light is subdivided, and the constructive/destructive interference of the external light is weakened, thereby improving the rainbow mura phenomenon. In addition, it provides an effect of reducing reflectance by offsetting external light.

Conventionally, in order to improve the rainbow mura phenomenon, a separate optical film is bonded onto the over coating layer 180 through an adhesive layer, but according to an embodiment of the present disclosure, the rainbow mura phenomenon may be improved through a plurality of lens (LS) structures provided in a color filter without using a separate optical film. Accordingly, the structure and process steps of the display device 100 are simplified and may be implemented to have a thinner thickness.

The plurality of lenses LS provided in each of the plurality of color filters 170 may have an amorphous structure having a non-uniform size. For example, the diameters and/or shapes of the plurality of lenses LS are not the same and may be irregularly formed. At least some of the plurality of lenses LS provided in one color filter 170 may be disposed to overlap each other. Further, ends of the plurality of lenses LS provided in one color filter 170 may be disposed to be in contact with each other. As described above, when each of the plurality of color filters 170 includes a plurality of lenses LS having an amorphous structure, reflectance may be reduced, and the rainbow mura phenomenon may be improved.

The color filter 170 including the lens LS having an amorphous structure may be formed by an inkjet printing process. In this case, the ink for forming a color filter may have hydrophilic properties. Accordingly, when the hydrophilic color filter forming ink is jetted on the touch buffer layer TBUF having hydrophobic properties, the wettability of the color filter forming ink with respect to the touch buffer layer TBUF is low so that when cured, the lens LS-shaped color filter 170 may be formed. Jetting of the ink for forming a color filter may be continuously performed several times, and cured to form a plurality of atypical lenses LS.

In order to more effectively reduce the reflectance, the width and aspect ratio of each of the plurality of lenses LS may be adjusted. For example, a width of each of the plurality of lenses LS provided in each of the plurality of color filters 170 may be 15 μm to 55 μm, and an aspect ratio may be 10% to 25%. More specifically, the width of each of the plurality of lenses LS may be 15 μm to 30 μm, and the aspect ratio may be 15% to 25%. In this case, the aspect ratio represents the number of the height of the lens LS divided by the cross-sectional width of the lens LS as a ratio of 100. Within this range, when compared with a display device including a conventional color filter without a lens LS, reflectance is reduced. When the width of each of the plurality of lenses LS is less than 15 μm, specifically 9 μm or less, the total reflection component is extracted and the amount of reflected light tends to increase. In addition, when the width of the lens LS exceeds 15 μm, the higher the height of the lens LS under the same width condition, the lower the amount of reflected light. In addition, under the condition in which the aspect ratio of the lens LS is the same, the larger the width of the lens LS, the lower the amount of light. Accordingly, the rainbow mura phenomenon may be improved by reducing the reflectance by the plurality of lens LS patterns provided in the color filter 170 without providing a separate optical film and subdividing the spatial luminance distribution of external light. In another example, as shown in FIGS. 2-3, the plurality of lenses LS are disposed in the emission area of each sub-pixel and further extends onto an upper surface of the black matrix 160, such that a total area of the plurality of lenses LS is larger than that of the emission area of each sub-pixel in a plan view.

The over coating layer 180 is disposed on the color filter 170 and the black matrix 160. The over coating layer 180 planarizes the top surfaces of the color filter 170 and the black matrix 160. Accordingly, the over coating layer 180 may be formed to have a sufficient thickness to planarize the top surfaces of the color filter 170 and the black matrix 160.

The over coating layer 180 may be formed of a material having a refractive index larger than that of the color filter 170. For example, the refractive index (200 nm to 1650 nm wavelength) of the color filter 170 may be 1.42 to 1.83, and the refractive index (200 nm to 1650 nm wavelength) of the over coating layer 180 may be 1.52 to 1.93. Within this range, the optical properties are excellent. In this case, a difference in refractive index between the color filter 170 and the over coating layer 180 may be adjusted to 0.05 to 0.10. In this case, the image quality of the display device is not distorted, and the rainbow mura phenomenon may be improved. A large difference (for example, larger than 0.2) in refractive index may be more effective in improving the rainbow mura phenomenon, but distortion of image quality may occur, and if the difference in refractive index is too small (for example, less than 0.05), the rainbow mura phenomenon may occur.

For example, the over coating layer 180 may be formed of a transparent resin such as acrylic resin, silicone resin, polyester resin, or epoxy resin, but is not limited thereto. The over coating layer 180 may include a UV blocker or a UV absorber that blocks or absorbs light having a wavelength of 400 nm or less. Accordingly, deterioration of the display device 100 due to ultraviolet rays may be obviated or reduced. The UV blocker or UV absorber may be used without limitation as long as the UV blocker or UV absorber is a material used in the art. The cover member 190 is disposed on the over coating layer 180. The cover member 190 may be bonded onto the over coating layer 180 by the adhesive layer Adh. The cover member 190 protects the display device 100 from an external environment. The cover member 190 may be a glass substrate or a plastic substrate. For example, the plastic substrate may be selected from polyimide, polyethersulfone, polyethylene terephthalate, and polycarbonate, but is not limited thereto.

The adhesive layer Adh may be formed of a transparent adhesive resin such as an optically transparent adhesive (OCA) or an optically transparent resin, but is not limited thereto. The adhesive layer Adh may further include black colorants or two or more dyes having different colors. In this case, external light is absorbed by the adhesive layer Adh to reduce reflectance.

The display device 100 according to the exemplary embodiment of the present disclosure does not use a separate optical film, and each of the plurality of color filters 170 includes a plurality of lenses LS, so that the color filter 170 has a non-flat surface. Accordingly, the path of the light incident from the outside is variously changed, the spatial luminance distribution of the external light is subdivided, and the constructive/destructive interference of the external light is weakened, thereby improving the rainbow mura phenomenon. In addition, it provides an effect of reducing reflectance by offsetting external light. According to the exemplary embodiment of the present disclosure, since a separate optical film is not provided, the thickness of the display device can be made slim while improving the display quality, and the structure and process steps can be simplified.

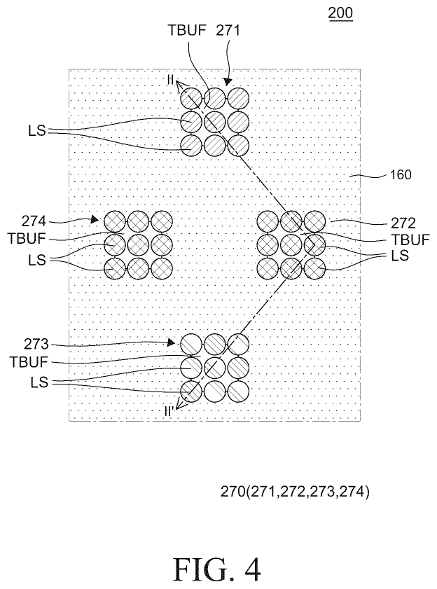

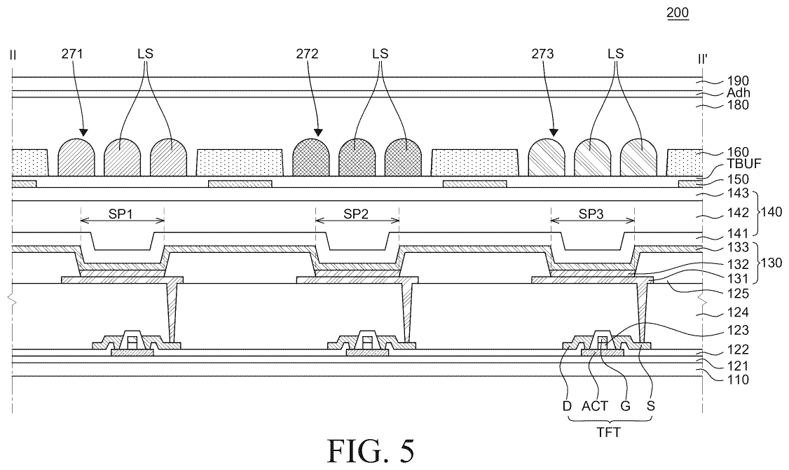

FIG. 4 is an enlarged plan view of one pixel in a display device according to another embodiment of the present disclosure. FIG. 5 is a cross-sectional view taken along the line II-II′ of FIG. 4.

Referring to FIGS. 4 and 5, a display device 200 according to another exemplary embodiment of the present disclosure includes a substrate 110, a thin film transistor TFT, a planarization layer 124, an organic light emitting element 130, an encapsulation layer 140, a touch sensor layer 150, a black matrix 160, a color filter 270, and an over coating layer 180, and the color filter 270 includes a plurality of lenses LS. The display device 200 illustrated in FIGS. 4 and 5 is substantially the same as the display device 100 illustrated in FIGS. 1 to 3 except for an arrangement structure of a plurality of lenses LS. Therefore, a redundant description of the redundant components will be omitted or briefly given.

In the display device 200, each of the plurality of color filters 270 includes a plurality of lenses LS. Specifically, each of the first color filter 271, the second color filter 272, the third color filter 273, and the fourth color filter 274 includes a plurality of lenses LS.

The plurality of lenses LS provided in each of the plurality of color filters 270 have the same size. For example, a plurality of lenses LS having the same size may be regularly arranged in each of the plurality of color filters 270. Such a structure may be implemented by jetting an ink for forming a color filter having a hydrophilic characteristic on a touch buffer layer TBUF having a hydrophobic characteristic, curing, and repeating jetting and curing again.

At least some of the plurality of lenses LS provided in each of the plurality of color filters 270 may be spaced apart from each other. Accordingly, at least some of the plurality of lenses LS provided in one color filter 270 may have an air gap between adjacent lenses LS. In this case, at least a portion of the touch buffer layer TBUF may be exposed due to an air gap existing between the lenses LS spaced apart from each other. When the touch buffer layer TBUF is exposed due to the air gap between the lenses LS spaced apart from each other as described above, reflectance may be reduced due to a change in the path difference of external light, and the rainbow mura phenomenon may be improved.

In order to further reduce the reflectance, the width and aspect ratio of each of the plurality of lenses LS may be adjusted. For example, a width of each of the plurality of lenses LS provided in each of the plurality of color filters 270 may be 15 μm to 55 μm, and an aspect ratio may be 10% to 25%. More specifically, the width of each of the plurality of lenses LS may be 15 μm to 30 μm, and the aspect ratio may be 15% to 25%. Within this range, when compared with a display device including a conventional color filter without a lens LS, reflectance is reduced. When the width of each of the plurality of lenses LS is less than 15 μm, specifically 9 μm or less, the total reflection component is extracted and the amount of reflected light tends to increase. In addition, under the condition that an aspect ratio of the lens LS is the same, the larger the diameter of the lens LS, the larger the area of the air gap between the lenses LS, so that the reflectance may be further reduced. In addition, under the conditions in which the diameter of the lens LS is the same, the greater the aspect ratio of the lens LS, the less the reflected light may be. On the other hand, when the diameter of the lens LS is small and the aspect ratio is large, the effect of reducing reflected light tends to be similar when compared with the case where the diameter of the lens LS is large and the aspect ratio is small. In this case, as the diameter of the lens LS increases, the shape of the lens LS may be visually recognized from the outside, so it may be desirable to form a structure in which the diameter of the lens LS is small and the aspect ratio is large in terms of display quality.

The display device 200 according to the exemplary embodiment of the present disclosure does not include a separate optical film, but reduces reflectance with a plurality of lens LS patterns provided in the color filter 270, and subdivides the spatial luminance distribution of external light to improve the rainbow mura phenomenon.

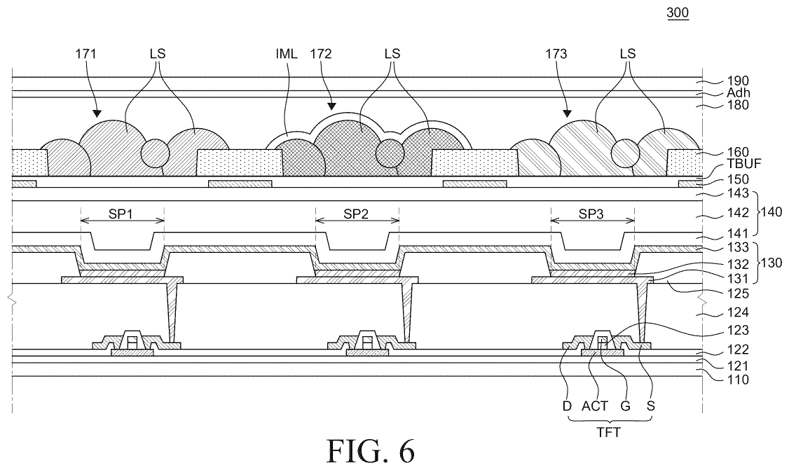

FIG. 6 is a cross-sectional view of a display device according to still another embodiment of the present disclosure. A display device 300 according to still another exemplary embodiment of the present disclosure includes a substrate 110, a thin film transistor TFT, a planarization layer 124, an organic light emitting element 130, an encapsulation layer 140, a touch sensor layer 150, a black matrix 160, a color filter 170, an over coating layer 180, and a refractive index matching layer IML. The color filter 170 includes a plurality of lenses LS. The display device 300 illustrated in FIG. 6 is substantially the same as the display device 100 illustrated in FIGS. 1 to 3 except that the display device 300 further includes a refractive index matching layer. Therefore, a redundant description of the redundant components will be omitted or briefly given.

In the display device 300, the refractive index matching layer IML is disposed on the color filter 170 corresponding to at least one of the plurality of sub-pixels SP1, SP2, SP3, and SP4. The refractive index matching layer IML may be disposed to reduce a difference in refractive index generated by using different materials to implement the color of each color filter 170.

For example, the first sub-pixel SP1, which is a red sub-pixel, and the third sub-pixel SP3, which is a blue sub-pixel, are formed of similar materials and have similar refractive indices, but the second sub-pixel SP2 and the fourth sub-pixel SP4, which are green sub-pixels, may have a large difference in refractive index from the first sub-pixel SP1 and the third sub-pixel SP3. In this case, the refractive index matching layer IML may be disposed on the color filter 170 corresponding to the green sub-pixel SP2 and/or the fourth sub-pixel SP4 to match the refractive indices of these color filters be similar to each other. For example, a refractive index difference between the over coating layer 180 and the second color filter 172 may be relatively larger than the refractive index difference between the over coating layer 180 and the first color filter 171 or the third color filter 173, thus a distortion of image quality may occur in the second sub-pixel SP2 corresponding to the second color filter 172. In this case, the refractive index matching layer IML may be disposed between the over coating layer 180 and the second color filter 172 to reduce or slow down the refractive index change between the over coating layer 180 and the second color filter 172, such that the distortion of image quality can be avoided, reduced or prevented in the second color filter 172.

The refractive index of the color filter 170 and the refractive index matching layer IML may be 1.42 to 1.83, and the refractive index (200 nm to 1650 nm wavelength) of the over coating layer 180 may be 1.52 to 1.93. Within this range, the optical properties are excellent. In this case, a difference between the refractive index of the color filter 170 and the refractive index matching layer IML and the refractive index of the over coating layer 180 may be 0.05 to 0.10. In this case, the image quality of the display device 300 is not distorted, and the rainbow mura phenomenon may be improved. A large difference in refractive index may be more effective in improving the rainbow mura phenomenon, but distortion of image quality may occur, and if the difference in refractive index is too small, the rainbow mura phenomenon may occur.

The refractive index matching layer IML may be formed to have a curved surface along the shape of the upper surface of the color filter 170 including a plurality of lenses LS. In this case, the effect of improving the rainbow mura and the effect of reducing the reflectance due to the structure of the plurality of lenses LS may be maintained high.

In the display device 300 according to the exemplary embodiment of the present disclosure, the refractive index matching layer IML is disposed on at least one color filter 170 to adjust the refractive index difference for each color, thereby further improving the reflectance.

In addition, the refractive index matching layer IML may also be applied to a structure in which at least some of the plurality of lenses LS provided in each of the plurality of color filters 270 are spaced apart from each other and have a void between adjacent lenses LS as shown in FIG. 5. In this case, because at least a part of the touch buffer layer TBUF is exposed due to the air gap, the refractive index matching layer IML may be disposed to be in contact with the exposed touch buffer layer TBUF.

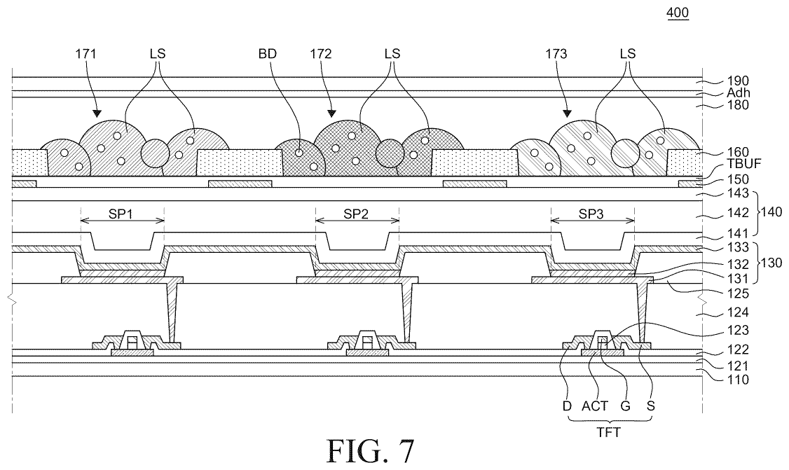

FIG. 7 is a cross-sectional view of a display device according to still another embodiment of the present disclosure. A display device 400 according to still another exemplary embodiment of the present disclosure includes a substrate 110, a thin film transistor TFT, a planarization layer 124, an organic light emitting element 130, an encapsulation layer 140, a touch sensor layer 150, a black matrix 160, a color filter 170, and an over coating layer 180, and the color filter 170 includes a plurality of lenses LS. The display device 400 illustrated in FIG. 7 is substantially the same as the display device 100 illustrated in FIGS. 1 to 3, except that the display device 400 further includes a scattering agent BD. Therefore, a redundant description of the redundant components will be omitted or briefly given.

At least some of the plurality of color filters 170 include a scattering agent BD dispersed in the color filter 170. For example, the scattering agent BD may be dispersed in the first color filter 171, the second color filter 172, the third color filter 173, and the fourth color filter 174. However, the present disclosure is not limited thereto, and depending on optical properties, the scattering agent BD may be dispersed only in some color filters 170, or may be dispersed to have different concentrations for each color of the color filter 170.

The scattering agent BD dispersed in the color filter 170 scatters external light to weaken the intensity of constructive interference and destructive interference, thereby further improving the rainbow mura phenomenon.

The color filter 170 in which the scattering agent BD is dispersed may be formed by the above-described inkjet process after adding the scattering agent BD to the ink for forming the color filter.

For example, the scattering agent BD may include a material selected from SiO₂, Al₂O₃, Na₂O, MgO, CaO, K₂O, TiO₂, and the like. These materials scatter light to suppress a decrease in display quality due to external light.

The scattering agent BD may be a round bead such as a circle or an oval shape. When the scattering agent BD has an angulated shape, reflected light such as sparkling is formed, which may be limited in lowering the reflectance.

Although not illustrated in the drawings, when necessary, a refractive index matching layer may be further disposed on at least some of the plurality of color filters 170.

The display device 400 according to the exemplary embodiment of the present disclosure may reduce reflectance by a plurality of lens LS patterns provided in the color filter 170, more effectively reduce reflected light by dispersing the scattering agent BD in the color filter 170, and improve the rainbow mura phenomenon by subdividing the spatial luminance distribution of external light.

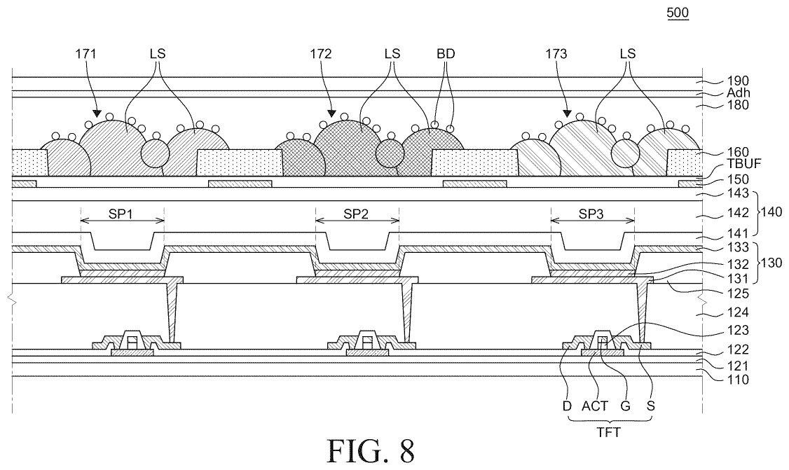

FIG. 8 is a cross-sectional view of a display device according to still another embodiment of the present disclosure. A display device 500 according to still another exemplary embodiment of the present disclosure includes a substrate 110, a thin film transistor TFT, a planarization layer 124, an organic light emitting element 130, an encapsulation layer 140, a touch sensor layer 150, a black matrix 160, a color filter 170, and an over coating layer 180, and the color filter 170 includes a plurality of lenses LS. The display device 500 illustrated in FIG. 8 is substantially the same as the display device 400 illustrated in FIG. 7 except that positions in which the scattering agent is included are different. Therefore, a redundant description of the redundant components will be omitted or briefly given.

The scattering agent BD may be disposed on at least some of the plurality of color filters 170. The scattering agent BD may be disposed on at least some color filters 170 as needed, or may be disposed above all color filters 170. In such a structure, after forming the plurality of lenses LS, the scattering agent BD is blown on the lens LS. It may be formed by applying a spray method such as spray roasting, but is not limited thereto.

The scattering agent BD scatters external light to weaken the intensity of constructive interference and destructive interference, thereby further improving the rainbow mura phenomenon. Accordingly, the display quality of the display device 500 may be improved.

Since the material or shape of the scattering agent BD is the same as described above, a redundant description will be omitted or briefly given.

The display device 500 according to the exemplary embodiment of the present disclosure does not include a separate optical film, reduces the reflectance with a plurality of lens LS patterns provided in the color filter 170, and applies the scattering agent BD onto the color filter 170 to more effectively reduce the reflected light, and may improve the rainbow mura phenomenon by subdividing the spatial luminance distribution of external light. It is to be noted that although FIGS. 2 to 8 illustrate various example structures of the display device by way of example only, but the present disclosure is not limited thereto. For example, various other structures may also be applied in the display device of the present disclosure, and thus one or more components of the display device shown in FIGS. 2 to 8 may be variously changed or omitted when necessary.

Hereinafter, the effects of the present disclosure described above will be described in more detail with reference to embodiments. However, the following examples are for illustration of the present disclosure, and the scope of the present disclosure is not limited by the following examples.

### Experimental Example

Simulation was performed to find out the optical characteristics of the display device including the color filter having the structure shown in FIGS. 4 to 5. For each specimen, the diameter, height, and aspect ratio of the lens were different as shown in Table 1 below, and their optical properties were evaluated. For optical properties, when the color filter does not include a plurality of lenses and has the same structure as the related art, the relative amount of reflected light of each specimen is expressed as a percentage based on the amount of reflected light. The results of this are shown in Table 1.

TABLE 1

| | | Aspect ratio | Amount of |
|---|---|---|---|
| Diameter | Height | (%) | reflected light |

| | | | | | |
|---|---|---|---|---|---|
| 5 | μm | 1.1 | μm | 22 | 115.56% |
| 9 | μm | 1.98 | μm | 22 | 101.92% |
| 9 | μm | 0.99 | μm | 11 | 110.1%. |
| 17 | μm | 3.74 | μm | 22 | 87.22% |
| 17 | μm | 1.87 | μm | 11 | 97.05% |
| 51 | μm | 11.22 | μm | 22 | 73.82% |
| 51 | μm | 5.61 | μm | 11 | 86.53% |

Referring to Table 1, when the color filter is composed of a plurality of lenses, it may be seen that the amount of reflected light varies from 115.56% to 73.82% as the diameter of each of the plurality of lenses increases from 5 μm to 51 μm.

Specifically, when the diameter of the lens is 9 μm or less, it can be seen that the amount of reflected light increased compared to the control group regardless of the aspect ratio. It can be assumed that this is due to the extraction of the total reflection component caused by external light without disappearing from the inside. When the diameter of the lens is 17 μm or more, it can be seen that the amount of reflected light decreases.

When a plurality of lenses have a structure that is regularly arranged with the same size, as the diameter of the lens increases from 17 μm to 51 μm, the voids between the lenses increase and the amount of reflected light decreases.

Under the conditions in which the diameter of the lens is the same, the amount of reflected light tends to be further reduced when the height of the lens is high and the aspect ratio is large.

From this, it may be seen that the color filter is composed of a plurality of lenses, and at this time, as the diameter of each of the plurality of lenses is larger and the aspect ratio is increased, the amount of reflected light is further reduced compared to the conventional structure in which the plurality of lenses is not provided.

The exemplary embodiments of the present disclosure can also be described as follows:

According to an aspect of the present disclosure, a display device includes a substrate on which a plurality of sub-pixels is defined, a thin film transistor disposed on the substrate, a planarization layer disposed on the thin film transistor, an organic light emitting element disposed on the planarization layer so as to correspond to each of the plurality of sub pixels, an encapsulation layer disposed on the organic light emitting element, a touch sensor layer disposed on the encapsulation layer and including a plurality of touch electrodes, a touch buffer layer disposed on the touch sensor layer, a plurality of color filters disposed to correspond to each of the plurality of sub-pixels on the touch buffer layer, a black matrix partitioning each of the plurality of color filters, and an over coating layer covering the black matrix, wherein each of the plurality of color filters includes a plurality of lenses.

According to another feature of the present disclosure, a width of each of the plurality of lenses may be 15 μm to 55 μm, and an aspect ratio may be 10% to 25%.

According to another feature of the present disclosure, the touch buffer layer may be hydrophobic.

According to another feature of the present disclosure, the size of each of the plurality of lenses provided in each color filter may be non-uniform.

According to another feature of the present disclosure, at least some of a plurality of lenses provided in each color filter may overlap each other.

According to another feature of the present disclosure, ends of the plurality of lenses provided in each color filter may be disposed to contact each other.

According to another feature of the present disclosure, the sizes of a plurality of lenses provided in each color filter may be the same.

According to another feature of the present disclosure, at least some of a plurality of lenses provided in each color filter may be spaced apart and have an air gap between adjacent lenses.

According to another feature of the present disclosure, at least some of the plurality of lenses provided in each color filter may be spaced apart from each other to expose at least a part of the touch buffer layer.

According to another feature of the present disclosure, at least a portion of the touch buffer layer may directly contact the over coating layer.

According to another feature of the present disclosure, at least one of the plurality of color filters may further include a refractive index matching layer disposed on the plurality of lenses, and the refractive index matching layer may be in direct contact with at least a part of the touch buffer layer.

According to another feature of the present disclosure, a cover member bonded onto the over coating layer through the adhesive member may be further included.

According to another feature of the present disclosure, at least one of the plurality of color filters may further include a refractive index matching layer disposed on the plurality of lenses.

According to another feature of the present disclosure, the refractive index matching layer may have a curved surface along the shape of an upper surface of the plurality of lenses.

According to another feature of the present disclosure, a refractive index of the refractive index matching layer may be larger than that of the at least one color filter, and smaller than that of the over coating layer.

According to another feature of the present disclosure, the plurality of sub-pixels may include a red sub-pixel, a green sub-pixel, and a blue sub-pixel, and the refractive index matching layer may be disposed on a color filter among the plurality of color filters, corresponding to the green sub-pixel.

According to another feature of the present disclosure, at least some of the plurality of color filters may further include a scattering agent dispersed in the plurality of lenses.

According to another feature of the present disclosure, at least some of the plurality of color filters may further include a scattering agent dispersed on the plurality of lenses.

According to another feature of the present disclosure, a refractive index of the over coating layer may be larger than that of each of the plurality of color filters.

According to another feature of the present disclosure, the plurality of lenses may have an amorphous structure and are irregularly arranged.

According to another feature of the present disclosure, the display device may further include a thin film transistor disposed on the substrate; a planarization layer disposed on the thin film transistor; an organic light emitting element disposed on the planarization layer so as to correspond to each of the plurality of sub-pixels; an encapsulation layer disposed on the organic light emitting element; a touch sensor layer disposed on the encapsulation layer and including a plurality of touch electrodes; and a touch buffer layer disposed on the touch sensor layer, wherein the plurality of color filters are disposed on the touch buffer layer.

According to another feature of the present disclosure, a distance between two adjacent black matrices may be greater than a distance between adjacent banks defining an emission area of each sub-pixel.

Although the exemplary embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate on which a plurality of sub-pixels is defined;
a thin film transistor disposed on the substrate;
a planarization layer disposed on the thin film transistor;
an organic light emitting element disposed on the planarization layer so as to correspond to each of the plurality of sub-pixels;
an encapsulation layer disposed on the organic light emitting element;
a touch sensor layer disposed on the encapsulation layer and including a plurality of touch electrodes;
a touch buffer layer disposed on the touch sensor layer;
a plurality of color filters disposed on the touch buffer layer so as to correspond to each of the plurality of sub-pixels;
a black matrix partitioning each of the plurality of color filters; and
an over coating layer covering the black matrix, wherein each of the plurality of color filters includes a plurality of lenses.

2. The display device according to claim 1, wherein a width of each of the plurality of lenses is 15 μm to 55 μm and an aspect ratio is 10% to 25%.

3. The display device according to claim 1, wherein the touch buffer layer is hydrophobic.

4. The display device according to claim 1, wherein the size of each of the plurality of lenses provided in each of the color filters is non-uniform.

5. The display device according to claim 4, wherein at least some of the plurality of lenses provided in each of the color filters overlap each other.

6. The display device according to claim 4, wherein ends of the plurality of lenses provided in each of the color filters are disposed to be in contact with each other.

7. The display device according to claim 1, wherein the sizes of the plurality of lenses provided in each of the color filters are the same.

8. The display device according to claim 7, wherein at least some of the plurality of lenses provided in each of the color filters are spaced apart from each other and have an air gap between adjacent lenses.

9. The display device according to claim 7, wherein at least some of the plurality of lenses provided in each of the color filters are spaced apart from each other to expose at least a part of the touch buffer layer.

10. The display device according to claim 9, wherein at least a part of the touch buffer layer directly contacts the over coating layer.

11. The display device according to claim 10, wherein at least one of the plurality of color filters further includes a refractive index matching layer disposed on the plurality of lenses, and
the refractive index matching layer is in direct contact with at least a part of the touch buffer layer.

12. The display device according to claim 1, further comprising: a cover member bonded onto the over coating layer through an adhesive member.

13. The display device according to claim 1, wherein at least one of the plurality of color filters further includes a refractive index matching layer disposed on the plurality of lenses.

14. The display device according to claim 13, wherein the refractive index matching layer has a curved surface along the shape of an upper surface of the plurality of lenses.

15. The display device according to claim 13, wherein a refractive index of the refractive index matching layer is larger than that of the at least one color filter, and smaller than that of the over coating layer.

16. The display device of claim 11, wherein the plurality of sub-pixels includes a red sub-pixel, a green sub-pixel, and a blue sub-pixel, and the refractive index matching layer is disposed on a color filter among the plurality of color filters, corresponding to the green sub-pixel.

17. The display device according to claim 1, wherein at least some of the plurality of color filters further include a scattering agent dispersed in the plurality of lenses.

18. The display device according to claim 1, wherein at least some of the plurality of color filters further include a scattering agent dispersed on the plurality of lenses.

19. The display device according to claim 1, wherein the plurality of lenses have an amorphous structure and are irregularly arranged.

20. The display device according to claim 1, wherein a distance between two adjacent black matrices is greater than a distance between adjacent banks defining an emission area of each sub-pixel.
